(19) United States
(12) Patent Application Publication
(10) Pub. No.: US 2010/0053862 A1
(43) Pub. Date: Mar. 4, 2010

(54) MODULAR DIGITAL IMAGE DISPLAY DEVICES AND METHODS FOR PROVIDING THE SAME

(75) Inventor: Steven R. Pargman, Palm Springs, CA (US)

Correspondence Address: ROPES & GRAY LLP, PATENT DOCKETING 39/361, 1211 AVENUE OF THE AMERICAS, NEW YORK, NY, 10036-8704, US

(73) Assignee: BURNES HOME ACCENTS, LLC, Round Rock, TX (US)

(21) Appl. No.: 12/553,312

(22) Filed: Sep. 3, 2009

Related U.S. Application Data
(60) Provisional application No. 61/094,177, filed on Sep. 4, 2008.

(51) Int. Cl. H05K 5/00

(52) U.S. Cl. 361/679.01

(57) ABSTRACT

Digital image display devices and methods for providing the same are provided. Such devices may include an electronic component for displaying digital images and a housing with a cavity for receiving the electronic component. The electronic component may include a display device, a processor, a battery, an input device, a storage device, and an I/O interface device. The electronic component may be capable of electrically coupling with an external power source, portable storage media or another electronic device. The electronic component may be interchangeable amongst a plurality of housings.

### FIELD OF THE INVENTION

In one embodiment, the present invention relates to apparatus and methods for displaying digital images.

### BACKGROUND OF THE INVENTION

Various factors limit the functionality of traditional digital image display devices. For example, most traditional digital image frames have standard rectilinear shapes that either attach to a vertical surface or rest on a horizontal surface. For support on a horizontal surface, a rigid support member is typically attached to a digital frame by a hinge with a limited range of motion. This configuration limits the functionality of traditional digital frames by restraining their use to substantially flat surfaces of a sizable area. This configuration also limits the angle at which a frame can be positioned and the angle at which it can be viewed. Moreover, traditional digital image frames are generally designed to be viewed only from the front and typically include an unsightly rear backing with exposed electronic connectors. As a result, many users only place digital frames in locations that hide the rear of the frame.

### SUMMARY OF THE INVENTION

Digital image display devices and methods for providing the same are provided. Such devices may include an electronic component for displaying digital images and a housing for receiving the electronic component. The electronic component may include a display device, and the housing may include an aperture corresponding to the display device. In addition to a display device, the electronic component may also include a processor, a battery, an input device, a storage device, and an I/O interface device. The electronic component may be capable of electrically coupling with an external power source, portable storage media or another electronic device. The electronic component may be interchangeable amongst a plurality of housings.

In accordance with one embodiment, a digital image display device may include a housing and an electronic component disposed within the housing. The housing may include an aperture and a plurality of flexible appendages. The electronic component may include a display device visible through the apertures and a processor. The display device may be electrically coupled to the processor, and the display device may display one or more digital images.

In accordance with one embodiment, a digital image display device may include a housing and an interchangeable electronic component disposed in the housing. The housing may include an aperture and a plurality of flexible appendages. The interchangeable electronic component may include a processor and a display device. The processor may be electrically coupled to the display device, and the display device may display one or more digital images. The interchangeable electronic component may be removable from the digital image display device without tools. For example, a user may be able to remove the interchangeable electronic component with her hands.

In accordance with one embodiment of the present invention, a digital image display device may include a housing and an electronic component disposed within the housing. The housing may include an aperture and may be formed from a flexible material. The electronic component may include a display device visible through the aperture and a processor. The display device may be electrically coupled to the processor, and the display device may display one or more digital images.

In accordance with one embodiment of the present invention, a method for providing a digital image display device is provided. The method may include providing an electronic component that includes a processor electrically coupled to a display device for displaying one or more digital images. The method may also include providing an assortment of housings from which a consumer can select at least one housing. Each housing in the assortment may include a cavity for receiving the electronic component, an aperture corresponding to the display device and a plurality of flexible appendages.

### BRIEF DESCRIPTION OF THE DRAWINGS

Further features of the invention, its nature and various advantages will be more apparent upon consideration of the following detailed description, taken in conjunction with the accompanying drawings, in which like reference characters refer to like parts throughout, and in which:

FIG. 1 is a simplified schematic of a display device in accordance with various embodiments of the present invention;

FIG. 2A is a front perspective view of a housing in accordance with one embodiment of the present invention;

FIG. 2B is a side cross-sectional view of a housing in accordance with one embodiment of the present invention;

FIG. 3 is a front perspective view of a housing in accordance with another embodiment of the present invention;

FIG. 4 is a front perspective view of a housing in accordance with another embodiment of the present invention;

FIG. 5 is a front perspective view of an electronic component for use in a display device in accordance with one embodiment of the present invention;

FIG. 6 is a front perspective view of a display device in accordance with one embodiment of the present invention; and

FIG. 7 is an illustrative flowchart for providing a display device in accordance with one embodiment of the present invention.

### DETAILED DESCRIPTION OF THE INVENTION

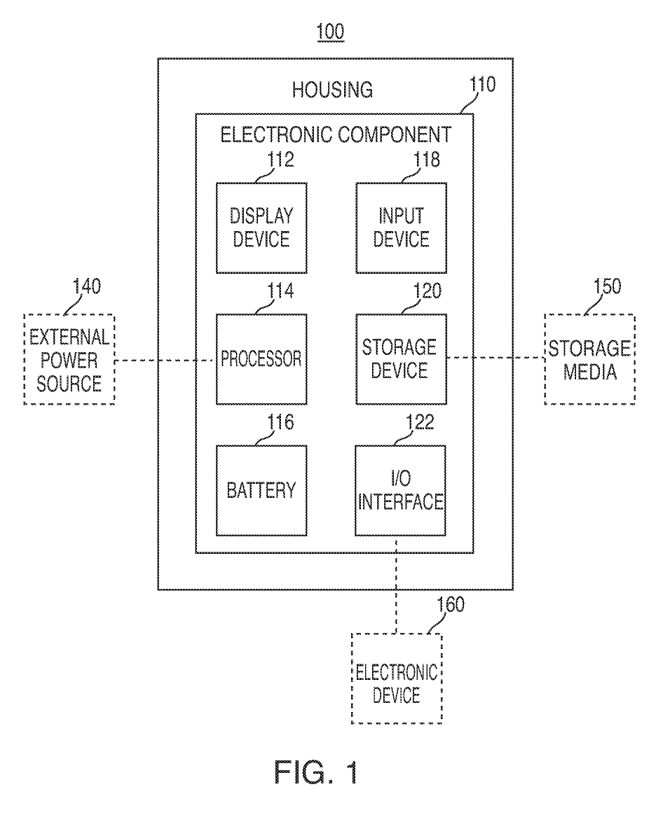

FIG. 1 includes display device 100 in accordance with one embodiment of the present invention. Device 100 can be used to display digital images. As used herein, the terms “image” and “digital image” are used to describe any digital image, photograph, video or other file that has a visual component.

Device 100 may include electronic component 110. For example, device 100 may include a housing having a cavity and electronic component 110 may be disposed in the cavity. Electronic component 110 may be interchangeable among one or more housings. For example, component 110 may be combined with any of a variety of housings to form an instance of device 100.

Electronic component 110 may include display device 112 and processor 114. Display device 112 may be operable to display digital images. Display device 112 may, for example, be an LCD display. Display device 112 may be of any suitable size for viewing digital images (e.g., 0.75″ diagonal, 1.5″ diagonal, 2.4″ diagonal, 3.5″ diagonal, 4″ diagonal, 4.3″ diagonal, 7″ diagonal or 8″ diagonal). Display device 112 may be electrically coupled to processor 114. Processor 114 may be any suitable processor for controlling display device 112 (e.g., a microprocessor).

Electronic component 110 may also include battery 116 that is electrically coupled to circuitry within electronic component 110. Battery 116 may provide electric power to electronic component 110 and its various subsystems, such as display device 112 and processor 114. Battery 116 may include one or more electrochemical batteries. Battery 116 may, for example, be a rechargeable battery. Electronic component 110 may include a physical interface (e.g., a connector) for electrically coupling with external power source 140 (e.g., an AC wall outlet) to charge battery 116. An AC to DC converter may be provided externally to electronic component 110 or may be provided through circuitry in electronic component 110. Electronic component 110 may include circuitry (e.g., in processor 114) for monitoring and controlling the charging of battery 116. Electronic component 110 may also include circuitry (e.g., in processor 114) for controlling the distribution of electric power from battery 116. In some embodiments, battery 116 may be one or more replaceable batteries (e.g., button cell batteries, AAA batteries or AA batteries).

Electronic component 110 may include input device 118 that is electrically coupled to processor 114. A user may be able to interact with input device 118 to provide user inputs (e.g., turn on, next photograph, previous photograph or play slideshow). Input device 118 may include one or more mechanical structures (e.g., buttons or levers) for receiving user inputs. Input device 118 may be combined with display device 112 in the form of a touch-screen panel that can both display digital images and receive user inputs. In some embodiments, input device 118 may include a voice recognition system for receiving user inputs.

Electronic component 110 may include storage device 120 that is electrically coupled to processor 114. Storage device 120 may be operable to store one or more digital images. Storage device 120 may be any suitable data storage device. For example, storage device 120 may be a magnetic hard disk drive or flash memory. Storage device 120 may be electrically coupled to display device 112 such that digital images stored on storage device 120 may be displayed on display device 112. Storage device 120 may store software for use by processor 114.

In some embodiments, storage device 120 may be operable to access portable storage media 150. Storage device 120 may include a physical interface (e.g., a connector) for electrically coupling with portable storage media 150. Storage media 150 may be portable storage media suitable for storing one or more digital images. For example, portable storage media 150 may be a flash memory card or a portable USB flash drive. Portable storage media 150 may also store software for use by processor 114. For example, portable storage media 150 may store an updated version of software for transfer to storage device 120 and subsequent use by processor 114. Storage device 120 may access portable storage media 150 in addition to any internal storage or memory (e.g., a hard disk drive or internal flash memory). For example, electronic component 110 may be able to download one or more digital images from storage media 150 to internal storage in storage device 120. In this example, the one or more downloaded images may be stored on storage device 120 indefinitely and available for display on display device 112. In another example, electronic component 110 may be operable to upload one or more digital images from internal storage in storage device 120 to storage media 150. In this manner, a user can share copies of digital images stored in electronic component 110 by uploading them to storage media 150. Both uploading and downloading of digital images to and from, respectively, storage media 150 may be initiated by a user (e.g., by providing a user input through input device 118). In some embodiments, transferring images to or from storage media 150 may be initiated automatically when the media is connected to component 110.

In some embodiments, storage device 120 may not include internal storage media and electronic component 110 may only be able to display images stored on portable storage media 150. In some embodiments, storage device 120 may include a cavity for receiving portable storage media 150 (e.g., an SD memory card slot) so that the portable media is protected inside electronic component 110. In some embodiments, device 100 may include one or more cavities or pockets such that each cavity can hold an instance of storage media 150. For example, each instance of storage media 150 may include a different set of digital images such that a user can display different sets of images by changing which storage media 150 is connected to electronic component 110.

Electronic component 110 may include I/O interface 122 that is electrically coupled to processor 114. I/O interface 122 may be operable to interface with other electronic devices. For example, I/O interface 122 may interface with electronic device 160 (e.g., a computer, a digital camera or a printer). In some embodiments, I/O interface 122 may interface with electronic device 160 that is another instance of electronic component 110. For example, one or more digital images stored in a first electronic component can be transferred to a second electronic component through an I/O interface. I/O interface 122 may include a physical interface (e.g., a connector) for electrically coupling electronic component 110 with electronic device 160. I/O interface 122 may be able to communicate with electronic device 160 using one or more suitable protocols. For example, I/O interface 122 may be able to communicate with electronic device 160 using a Universal Serial Bus (USB) or Firewire protocol. Depending on the protocols supported, I/O interface 122 may include circuitry for processing signals transmitted to or received from electronic device 160. In some embodiments, I/O interface 122 may be operable to interface with electronic device 160 wirelessly (e.g., using an IEEE 802.11 standard).

I/O interface 122 may be operable to receive digital images from electronic device 160. Similar to storage device 120 communicating with storage media 150, I/O interface 122 may allow electronic component 110 to download digital images from electronic device 160 and store them in storage device 120. I/O interface 122 may be operable to transmit digital images to electronic device 160. For example, I/O interface 122 may allow a user to share copies of digital images stored on component 110 by uploading them to another electronic device. Similar to initiating transfers with storage media 150, uploading and downloading of digital images to and from, respectively, electronic device 160 may be initiated by a user (e.g., by providing a user input through input device 118 or electronic device 160) or automatically upon connection to electronic device 160.

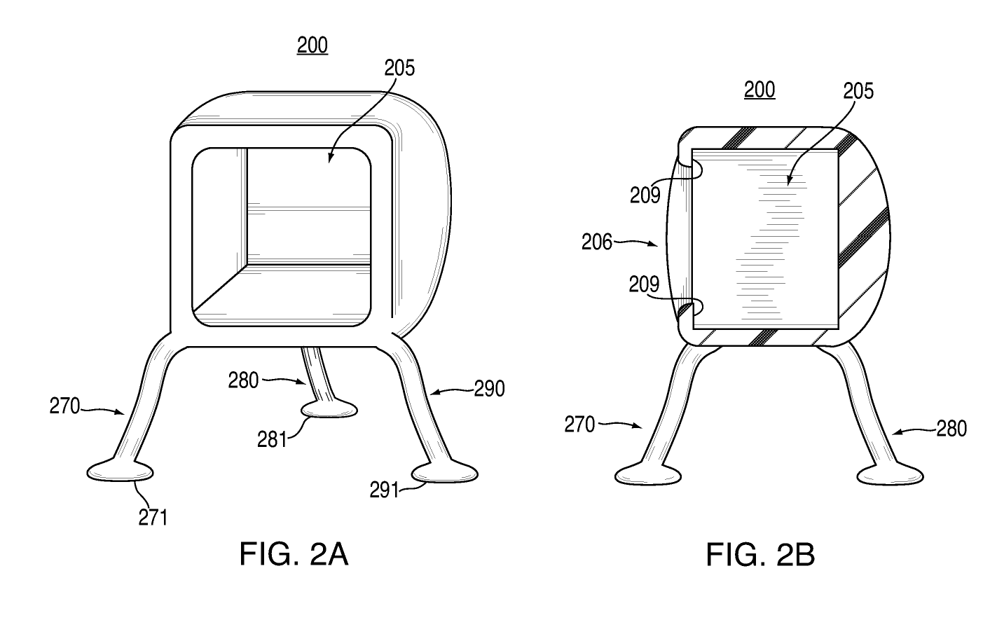

FIGS. 2A and 2B include housing 200 in accordance with one embodiment of the present invention. Housing 200 can include cavity 205 for receiving an electronic component (see, e.g., electronic component 110). Cavity 205 may be sized to correspond to a standard electronic component size. In some embodiments, cavity 205 may include a compressible (e.g., made from foam) lining for protecting an electronic component stored therein from shock. Housing 200 and cavity 205 may be configured such that a user can install a component in the cavity and/or remove a component from the cavity without using tools.

Housing 200 can be made from a flexible material such as flexible polyvinyl chloride (PVC) or a rubber composite. Flexibility in housing 200 may allow a user to stretch open cavity 205 for inserting an electronic component through aperture 206. After being stretched open, cavity 205 may resume its previous shape such that an electronic component disposed therein does not move around or fall out. In some embodiments, the interior surface of cavity 205 may be formed to create friction with an electronic component inserted therein. Such friction may prevent the component from moving within the cavity or falling out of the cavity. For example, the interior surface of cavity 205 may include PVC or a rubber material so that the interior surface creates friction with electronic components disposed therein. In some embodiments, housing 200 may be formed entirely from a single type of material (e.g., flexible PVC or a rubber composite). Housing 200 may include ridge 209 that surrounds one or more sides of aperture 206. For example, a ridge may be provided in just a single side of aperture 206, two opposite sides of aperture 206 or four or more sides of aperture 206. Ridge 209 may prevent an electronic device stored in cavity 205 from sliding out of the cavity.

In some embodiments, a variety of physical features may be provided on the inner surface of cavity 205 for coupling with an electronic component. For example, the inner surface of cavity 205 may include a set of physical features such that only electronic components with a complimentary set of physical features can be installed in the cavity. In some embodiments, the inner surface of cavity 205 may include a set of protrusions and/or indentations such that only electronic components with a complimentary set of protrusions and/or indentations can be installed in the cavity. In this manner, a manufacturer of electronic components and housings can prevent consumers from using generic electronic components or housings with their products.

Housing 200 may include one or more flexible appendages. Each flexible appendage may be composed of a single flexible material (e.g., flexible PVC or rubber) or multiple components that are flexibly coupled together. Housing 200 may include flexible appendages 270, 280 and 290 for supporting the device in an upright position. For example, flexible appendages 270, 280 and 290 may collectively form a tripod for supporting housing 200. A user may be able to adjust flexible appendages 270, 280 and 290 to support housing 200 on an uneven surface. For example, a user may adjust appendages 270, 280 and 290 to support housing 200 on a surface with deep grooves by adjusting the appendages such that they do not align with the grooves. A user may be able to adjust the height of housing 200, cavity 205 and any electronic component disposed therein by adjusting flexible appendages 270, 280 and 290. For example, adjusting the appendages to be spread apart may shorten the device. Moreover, a user may be able to support housing 200 on a small surface area by adjusting flexible appendages 270, 280 and 290. For example, a user may be able to adjust the appendages such that they are close together and the device may then be positioned on a small surface. A user may be able to adjust the orientation of cavity 205 and the viewing angle of any electronic component disposed therein by adjusting flexible appendages 270, 280 and 290. For example, a user may be able to adjust the flexible appendages such that cavity 205 and any electronic component disposed therein point in a particular direction.

Appendages 270, 280 and 290 may each include, respectively, base portions 271, 281 and 291. Each of the base portions may be located at the distal end of one of the appendages. The base portions may have a greater diameter than the flexible appendages. The increased diameter can provide more surface area along the bottom of the base portions and allow for increased contact with a surface supporting housing 200. The increased contact can make housing 200 more stable on the surface. The bottom surface of base portions 271, 281 and 291 may include a texture or coating to increase friction between the bottom surface of the base portions and a surface that is supporting housing 200. In some embodiments, the bottom surface of base portions 271, 281 and 291 may include a suction cup for coupling housing 200 with a supporting surface.

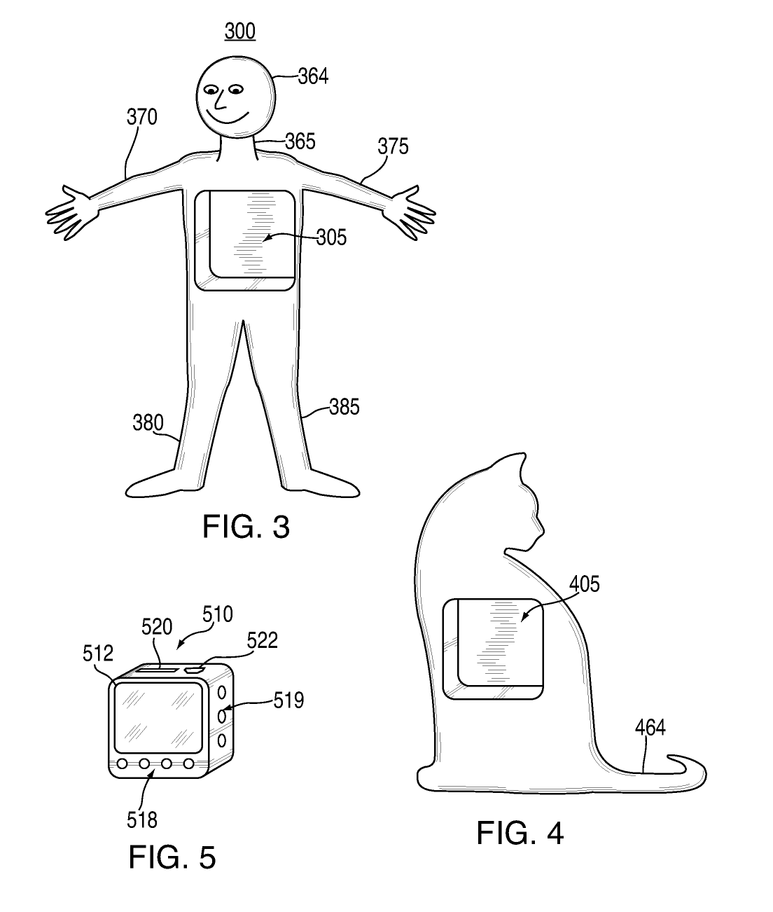

FIG. 3 includes housing 300 in accordance with one embodiment of the present invention. Housing 300 may be shaped to resemble a human form with cavity 305 in the torso. It is understood that cavity 305 may be provided in any portion of a housing shaped to resemble a human form, such as the head, without deviating from the spirit and scope of the present invention. Cavity 305 (see, e.g., cavity 205) may be sized to receive an electronic component (see, e.g., component 110) for displaying digital images. Cavity 305 may be the same dimensions as cavity 205 such that the same electronic component can be used in housing 300, housing 200 or any other housing having a similarly sized cavity. Moreover, if cavity 205 includes any physical features on its internal surface for coupling with an electronic component, cavity 305 may also include those features.

Any portion of housing 300 may be flexible. For example, housing 300 may include head 364 attached to flexible neck 365 such that a user can position the head to point in a particular direction. Housing 300 may include flexible appendages that resemble human arms and legs. For example, housing 300 may include appendages 370 and 375 that resemble arms and appendages 380 and 385 that resemble legs. One or more of appendages 370, 375, 380 and 385 may be positioned to support housing 300. For example, a user can position the appendages such that the housing resembles a person in a particular pose such as standing, sitting or reclining. The pose of housing 300 can be chosen such that it corresponds with an image displayed by an electronic component disposed in cavity 305. For example, a user can position housing 300 such that it is in an athletic pose if a sports image is being displayed by an electronic component in cavity 305. In some embodiments, housing 300 may be provided with one or more accessories (e.g., baseball bat or mortar board graduation cap) such that a user may couple an accessory corresponding to a displayed image with the housing. For example, a user may couple a baseball bat with one or more hands of housing 300 to correspond with one or more digital images involving baseball. In another example, a user may couple a mortar board graduation cap with head 364 to correspond with one or more digital images involving graduation. In some embodiments, all of housing 300 may be flexible. For example, all of housing 300 may be made from the same flexible material (e.g., flexible PVC or rubber).

FIG. 4 includes housing 400 in accordance with one embodiment of the present invention. Housing 400 may be shaped to resemble a cat form with cavity 405 in the torso for receiving an electronic component (see, e.g., electronic component 110) for displaying digital images. Housing 400 may include flexible appendage 464 in the form of a tail. It is understood that the housing forms provided in FIGS. 2-4 are merely illustrative and that any other housing forms having any arrangement of flexible appendages may be used without deviating from the spirit and scope of the present invention. Cavity 405 may be the same dimensions as cavity 205 such that the same electronic component can be used in housing 400, housing 300, housing 200 or any other housing having a similarly sized cavity. Moreover, if cavity 205 and cavity 305 include any physical features on their internal surfaces for coupling with an electronic component, cavity 305 may also include those features.

FIG. 5 includes electronic component 510 in accordance with one embodiment of the present invention. Electronic component 510 can display digital images (see, e.g., electronic component 110). Electronic component 510 may be sized and shaped such that it can be installed in any of a variety of housings, including housings 200, 300 or 400. Electronic component 510 may include display device 512 or other component for displaying digital images (see, e.g., display device 112). Display device 512 may be provided in component 510 such that the screen is visible when the component is installed in a housing. For example, display device 512 may be provided such that it aligns with an aperture (see, e.g., aperture 206) when component 510 is installed in a housing.

Electronic component 510 may include a processor for controlling the display of images (see, e.g., processor 114). Electronic component 510 may include a battery for powering the device (see, e.g., battery 116). A battery provided in electronic component 510 may be a permanently installed battery or may be one or more replaceable batteries. Component 510 may include one or more removable panels such that a user can access a battery in the component. In some embodiments, component 510 may include a connector for receiving electrical power to charge one or more rechargeable batteries in the component.

Electronic component 510 may include one or more input devices 518 for receiving user inputs (see, e.g., input device 118). For example, electronic component 510 may include buttons for receiving user inputs. In some embodiments, multiple input devices may be provided and each device may have a different function. In some embodiments, a single device (e.g., a touch pad or a joystick) may be provided such that a user can provide a variety of inputs through the single device. The complexity and quantity of input devices 518 may depend, for example, on the functionality and complexity of component 510. For example, input devices 518 may include only one button for turning component 510 on and off and one button for changing the digital image displayed on display device 512. In some embodiments, a broad range of functions can be provided by input devices 518. For example, different input devices can be associated with different sets of digital images such that a user can easily navigate between the sets by providing an input through the different input devices (e.g., pushing a button). In some embodiments, one input device may be associated with a print command such that, if a printer is connected to component 510, the image currently displayed on display device 512 is sent to the printer in response to a user providing an input through the input device. In some embodiments, an input device can be associated with transferring files such that, when a user provides an input through the device, one or more digital images are transferred to a portable storage media or other electronic device electrically coupled with component 510.

In some embodiments, electronic component 510 may include one or more input devices that are concealed when the component is installed in a housing (e.g., housings 200, 300 or 400). For example, component 510 may include one or more buttons 519 that are on the side or back of the component such that the buttons are hidden when the component is installed in a housing. Input devices that are concealed when component 510 is installed in a housing may correspond to functions that are infrequently used. For example, input devices that correspond to configuration functions may be infrequently used and may therefore be located on component 510 such that they are concealed when the component is installed in a housing. Input devices that are concealed when component 510 is installed in a housing may correspond to functions that are primarily used when component 510 is outside of a housing. For example, input devices that correspond to file transfer functions may be infrequently used and may therefore be located on component 510 such that they are concealed when the component is installed in a housing. In some embodiments, a housing for use with component 510 may include one or more flexible portions adjacent to the location of concealed input devices on the component. For example, buttons 519 may be able to receive user inputs when component 510 is installed in a housing by detecting when a user presses against a flexible portion of the housing at a location corresponding to the buttons.

In some embodiments, one or more input devices may be embedded in a housing for use with electronic component 510 and the component may electrically couple with the housing to receive user inputs provided through the input devices. For example, a housing may include one or more buttons on its external surface that a user can press to provide a user input, and an electronic component in the housing may receive the input through an electrical coupling with the housing. While the previous example discussed embedding one or more buttons in the external surface of a housing, it is understood that any other form of input devices may be embedded in a housing without deviating from the spirit and scope of the present invention. For example, capacitive sensors may be embedded in a housing such that a user can provide an input by touching a specific portion of the housing. In some embodiments, one or more capacitive sensors may be used such that a user can provide a different input by touching a different portion of the housing. For example, a housing may include flexible appendages that each resemble a human arm with a hand (see, e.g., appendages 370 and 375) and a user may be able to touch one appendage to provide a “Next Image” input and the other appendage to provide a “Previous Image” input. In another example, switches may be embedded in a housing such that a user can provide an input by bending a flexible appendage.

Electronic component 510 may include internal memory (see, e.g., storage device 120). In some embodiments, electronic component 510 may include an interface for receiving external storage media such as a flash memory card (see, e.g., storage media 150). For example, electronic component 510 may include connector 520 for receiving an external storage media. Connector 520 may, for example, be a connector for receiving a flash card. In some embodiments, connector 520 may be located such that it is only accessibly when component 510 is not installed in a housing. In other words connector 520 may be concealed when component 510 is installed in a housing. In some embodiments, connector 520 may be located such that it aligns with an aperture in a housing and can be accessed even if the component is installed in the housing. For example, if the location of connector 520 corresponds to an aperture in a housing, a user can conveniently insert external storage media into the connector without needing to remove component 510 from the housing.

Electronic component 510 may include a connector 522 (see, e.g., I/O interface 122) for interfacing with other electronic devices (see, e.g., electronic device 160). For example, connector 522 may be used to transmit digital images to or receive digital images from another electronic device. Like connector 520, connector 522 may be provided such that it is concealed when component 510 is installed in a housing, or connector 522 may be provided such that it aligns with an aperture in a housing and can be accessed when the component is installed in the housing. In the latter embodiment, a user may be able to conveniently couple electronic component 510 with another electronic devices without needing to remove the component from a housing.

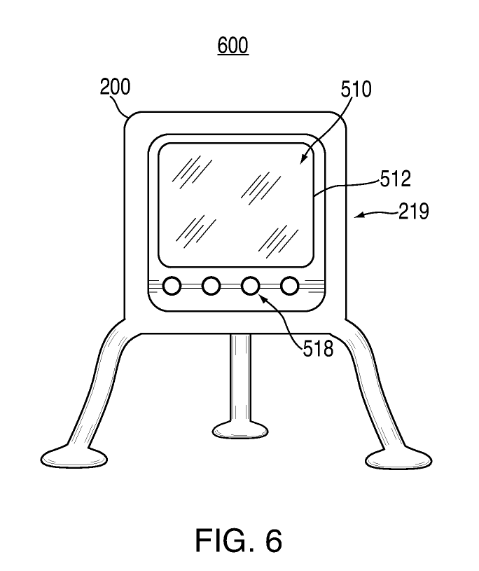

FIG. 6 includes device 600 in accordance with one embodiment of the present invention. Device 600 is formed by installing electronic component 510 in housing 200. Display device 512 and input devices 518 may be aligned with aperture 206 such that the display device and input devices are accessible when component 510 is installed in housing 200. In the embodiment shown in FIG. 6, buttons 519 and connectors 520 and 522 may be concealed when device 600 is assembled. If a user wanted to access one of buttons 519, the user may have to remove electronic component 500 from housing 200. However, if housing 200 includes flexible portion 219, a user may be able to press against the flexible portion to provide an input through buttons 519.

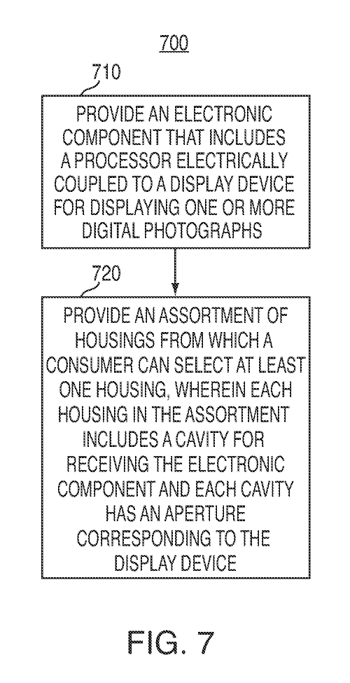

FIG. 7 shows flowchart 700 of a method for providing a digital image display device in accordance with one embodiment of the present invention. At step 710, an electronic component can be provided that includes a processor electrically coupled to a display device for displaying one or more digital images. The electronic component provided at step 710 may include an input/output interface, electrically coupled to the processor, for interfacing with other electronic devices or storage media. In some embodiments, the electronic component provided at step 710 may include a storage device, electrically coupled to the processor, for storing one or more digital images. In some embodiments, the electronic component provided at step 710 may include an input device, electrically coupled to the processor, for receiving user inputs. In some embodiments, the electronic component provided at step 710 may include a battery, electrically coupled to the processor, for powering the electronic component. For example, a component similar to component 510 may be provided to a consumer at step 710.

At step 720, an assortment of housings from which a consumer can select at least one housing may be provided. Each housing in the assortment may include a cavity for receiving the electronic component and each cavity may have an aperture corresponding to the display device of the previously provided electronic component. For example, an assortment of housings comparable to housing 200, housing 300 or housing 400 may be provided to a consumer. Each housing in the assortment may include a cavity for receiving an electronic component. Each housing may include one or more flexible appendages for supporting the housing. In some embodiments, a housing may include a plurality of apertures with one aperture corresponding to the location of an electronic component's display device and the other apertures corresponding to the locations of an electronic component's connectors or input devices.

In some embodiments, the assortment of housings may include housings having different colors or styles. In some embodiments, the assortment of housings may include housings having different themes (e.g., birthday, sports, graduation or animals).

It is to be understood that the foregoing is only illustrative of the principles of the invention, and that various modifications can be made by those skilled in the art without departing from the scope and spirit of the invention, and the present invention is limited only by the claims that follow.

What is claimed is:

1. A digital image display device comprising:
a housing including an aperture and a plurality of flexible appendages; and
an electronic component disposed within the housing, the electronic component including a display device visible through the aperture and a processor, wherein the display device is electrically coupled to the processor and the display device displays one or more digital images.

2. The device of claim 1, wherein the electronic component is removably disposed within the housing.

3. The device of claim 1, wherein the plurality of flexible appendages can be positioned to support the device.

4. The device of claim 1, further comprising:
an input device for receiving user inputs, wherein the input device is accessible through the first aperture and electrically coupled to the processor.

5. The device of claim 1, further comprising:
a second aperture in the housing; and
an input device for receiving user inputs, wherein the input device is accessible through the second aperture and electrically coupled to the processor.

6. The device of claim 1, wherein the electronic component is interchangeable amongst a plurality of housings, each housing of the plurality of housings having a different external shape.

7. The device of claim 6, wherein the housing can be stretched to remove the electronic component.

8. The device of claim 1, wherein the electronic component includes a storage device, electrically coupled to the processor, for storing at least one of the one or more digital images.

9. The device of claim 1, wherein the electronic component includes an input/output interface, electrically coupled to the processor, for interfacing with other electronic devices.

10. The device of claim 9, wherein:
the input/output interface includes one or more connectors for physically interfacing with other electronic devices; and
the housing includes one or more apertures allowing access to the one or more connectors.

11. The device of claim 1, wherein the electronic component includes a battery, electrically coupled to the processor, for powering the electronic component.

12. The device of claim 1, wherein each flexible appendage includes flexible polyvinyl chloride.

13. The device of claim 1, wherein the housing is made entirely of flexible polyvinyl chloride.

14. A digital image display device comprising:
a housing including an aperture and a plurality of flexible appendages; and
an interchangeable electronic component disposed in the housing and having a processor and a display device, wherein:
the processor is electrically coupled to the display device;
the display device displays one or more digital images; and
the interchangeable electronic component is removable from the device without tools.

15. A digital image display device comprising:
a housing including an aperture and being formed from a flexible material; and
an electronic component disposed within the housing, the electronic component including a display device visible through the aperture and a processor, wherein the display device is electrically coupled to the processor and the display device displays one or more digital images.

16. The device of claim 15, wherein the housing can be stretched to remove the electronic component without tools.

17. A method for providing a digital image display device, the method comprising:
providing an electronic component that includes a processor electrically coupled to a display device for displaying one or more digital images; and
providing an assortment of housings from which a consumer can select at least one housing, wherein each housing in the assortment includes a cavity for receiving the electronic component, an aperture corresponding to the display device and a plurality of flexible appendages.

18. The method of claim 17, wherein the providing an electronic component comprises:
providing an electronic component that includes a processor electrically coupled to:
a display device for displaying one or more digital images; and
an input/output interface for interfacing with other electronic devices.

19. The method of claim 17, wherein the providing an electronic component comprises:
providing an electronic component that includes a processor electrically coupled to:
a display device for displaying one or more digital images; and
a storage device for storing one or more digital images.

20. The method of claim 17, wherein the providing an electronic component comprises:
providing an electronic component that includes a processor electrically coupled to:
a display device for displaying one or more digital images; and
an input device for receiving user inputs.

21. The method of claim 17, wherein the providing an electronic component comprises:
providing an electronic component that includes a processor electrically coupled to:
a display device for displaying one or more digital images; and
a battery for powering the electronic component.

22. The method of claim 17, wherein each housing in the assortment includes:
a plurality of flexible appendages for supporting the housing.

23. The method of claim 22, wherein each housing in the assortment further includes:
a plurality of flexible appendages for depicting a pose.
